(19) United States
(12) Patent Application Publication
(10) Pub. No.: US 2007/0082414 A1
(43) Pub. Date: Apr. 12, 2007

(54) Perpendicular magnetic recording medium, method for production of the same, and magnetic recording apparatus

(75) Inventors: Sadayuki Watanabe, Kanagawa (JP); Yasushi Sakai, Tokyo (JP)

Correspondence Address: VENABLE LLP, P.O. BOX 34385, WASHINGTON, DC, 20043-9998, US

(73) Assignee: FUJI ELECTRIC DEVICE TECHNOLOGY CO., LTD., TOKYO (JP)

(21) Appl. No.: 10/578,681

(22) PCT Filed: Mar. 14, 2005
(86) PCT No.: PCT/JP05/04468

§ 371 Date: May 9, 2006

(30) Foreign Application Priority Data
Mar. 15, 2004 (JP) 2004-072598

(51) Int. Cl. H01L 21/00

(52) U.S. Cl. 438/3

(57) ABSTRACT

A perpendicular magnetic recording medium having compatibility between low noises and high thermal stability is provided. In the present medium having at least an underlayer, a magnetic recording layer, a protective layer and a lubricant layer sequentially stacked on a nonmagnetic substrate, the underlayer is composed from at least one element selected from Ru, Rh, Os, Ir and Pt, the magnetic recording layer has a granular structure, and its composition is Co_{100-a-b-c}PtₐCr_{b}B_{c})_{100-d}M_{d} (M is an oxide or a nitride of at least one element of Cr, Al, Ti, Si, Ta, Hf, Zr, Y and Ce, and a, b, c and d meet the condition of 0<a≦40, 2≦b ≦12, 0.5≦c≦5 and 4≦d≦12). A soft magnetic backing layer 2 and a seed layer 3 may be formed between the nonmagnetic substrate and the underlayer.

### TECHNICAL FIELD

The present invention relates to a perpendicular magnetic recording medium installed on a various kinds of magnetic recording apparatuses, a method for production of the same, and a magnetic recording apparatus using the perpendicular magnetic recording medium.

### BACKGROUND ART

As a technique for increasing magnetic recording density, attention is being given to perpendicular magnetic recording systems in which recording magnetization is perpendicular to the in-plane direction of a medium, in place of conventional longitudinal magnetic recording systems. A perpendicular magnetic recording medium consists mainly of a magnetic recording layer of a hard magnetic material, an underlayer for orienting the magnetic recording layer toward an intended direction, a protective layer protecting the surface of the magnetic recording layer, and a backing layer of a soft magnetic material serving to focus magnetic fluxes generated by a magnetic head which is used for recording on the recording layer. The soft magnetic backing layer may be omitted because recording is possible even if the layer is absent, although the performance of the medium is enhanced if the layer is present. A medium which does not have such a soft magnetic backing layer is called a single layer perpendicular magnetic recording medium (abbreviated as single layer perpendicular medium), and a medium having the soft magnetic backing layer is called a double layer perpendicular magnetic recording medium (abbreviated as double layer perpendicular medium). In the perpendicular magnetic recording medium (abbreviated as perpendicular medium), as in a longitudinal magnetic recording medium, noise reduction and high thermal stability should be mutually compatible for increasing the recording density.

Noise reduction is achieved by reducing the size of magnetic particles or reducing magnetic interactions between the magnetic particles. One of parameters including influences of the size of magnetic particles and representing the magnitude of the interactions between the particles is what is called a magnetic cluster size. A magnetic cluster consists of a plurality of magnetic particles, and the lower the interactions between the particles, the smaller the magnetic cluster size. For achieving noise reduction, the magnetic cluster size should be reduced. However, reduction of the magnetic cluster size means reduction of volume of the magnetic cluster, and the problem of so called thermal fluctuations arises. Namely, a written (recorded) signal is deteriorated, and data disappears. For overcoming this problem, the perpendicular magnetic anisotropy constant Ku of the magnetic recording layer should be increased. Furthermore, it is also necessary to improve an environmental resistance to prevent corrosion of materials for improving the reliability.

For the conventional longitudinal magnetic recording medium, various compositions and structures of magnetic recording layers, materials of nonmagnetic underlayers, and the like have been proposed. For commercially practical magnetic recording layers, an alloy having Co, Cr (hereinafter abbreviated as CoCr alloy) is used, and Cr is segregated in crystal particle boundaries to obtain isolated magnetic particles. Examples in which the CoCr alloy is used, utilize CoCrPt—X in the magnetic recording layer, in which the concentration of Cr is set to 12 to 26 atom %, and the ratio of the Cr concentration at the particle boundary is increased to 1.4 times as high as that with in particles to form a segregated structure (see, for example, Patent Document 1). In addition, there are examples in which CoCrPtBO is used (see, for example, Patent Document 2).

For other magnetic recording layer materials, magnetic recording layers called granular magnetic recording layers and using nonmagnetic nonmetallic materials such as, for example, oxides and nitrides as a particle boundary phase have been proposed (see, for example, patent Documents 3 and 4).

There are examples in which a heat treatment is carried out at 250 to 500° C. for 0.1 to 10 hours for achieving the segregated structure within a granular magnetic recording layer material (see, for example, Patent Documents 5 and 6). Recently, a granular medium using a CoCrPt—SiO₂ magnetic recording layer has been proposed, in which formation of the segregated structure has been achieved without a heat treatment (see, for example, Non-Patent Document 1). In Non-Patent Document 1, it has been found that the granular medium can reduce medium noises compared to the conventional medium using a CoCr alloy material as the magnetic recording layer, and has high Ku, a parameter for thermal stability. Therefore, the granular medium is expected as a promising material in the future.

In addition, there are examples in which a protective film, which consists of a layer having carbon as a main component as is used normally and multiple layers of metals such as Ti, is used for improving a corrosion resistance when the granular magnetic recording layer is used (see, for example, see Patent Document 7).

Patent Document 1: Japanese Patent Application Laid-Open No. 2002-358615

Patent Document 2: Japanese Patent Application Laid-Open No. 3-58316

Patent Document 3: U.S. Pat. No. 5,679,473

Patent Document 4: Japanese Patent Application Laid-Open No. 2001-101651

Patent Document 5: Japanese Patent Application Laid-Open No. 2000-306228

Patent Document 6: Japanese Patent Application Laid-Open No. 2000-311329

Patent Document 7: Japanese Patent Application Laid-Open No. 2001-43526

Non-Patent Document 1: T. Oikawa, “Microstructure and Magnetic properties of CoPtCr—SiO2 Perpendicular Recording Media”, IEEE Transactions on Magnetics, 38(5), 1976-1978 (September, 2002)

### DISCLOSURE OF THE INVENTION

### Problems to be Solved by the Invention

The inventors have conducted research on granular magnetic recording layer materials as magnetic recording layers of perpendicular media because they do not require a long-term and high-temperature heating step and are thus excellent in productivity, and particularly, the inventors study on CoPtCr-M (M is an oxide, a nitride or an oxide and nitride) granular perpendicular media. In the granular perpendicular medium, it is important to improve the crystallinity and orientation of CoPtCr (which forms ferromagnetic crystal particles) in terms of securing thermal stability, and to form an isolated structure (i.e. a segregated structure) by an oxide or a nitride (which forms a nonmagnetic particle boundary) in terms of noise reduction.

The conventional CoCr alloy using no granular structure requires a relatively high concentration, i.e. around 20 atom %, of Cr for increasing the Cr concentration in the particle boundary phase to render the phase nonmagnetic. On the other hand, it can be considered that the granular medium having an oxide or a nitride as a nonmagnetic particle boundary does not necessarily require Cr. However, as a result of conducting studies with attention given to the role of Cr in CoPtCr materials, the inventors have found that increasing the content of Cr has an effect of reducing magnetic interactions between ferromagnetic crystal particles and hence medium noises. However, on the other hand, it has also been found that Ku decreases to deteriorate the thermal stability, and resultantly, signal deterioration tends to be significant. If the amount of Cr is reduced for avoiding a decrease in Ku, the region of the particle boundary phase excessively expands when the proportion of the nonmagnetic particle boundary phase is simply increased for securing the isolated structure. As a result, the crystal particle diameter decreases to, for example, about 4 nm or less, the proportion of para magnetic particles changed from crystal particles which should be ferromagnetic by nature increases, and resultantly, a problem of thermal fluctuations (deterioration of thermal stability) arises. Thus, it is required to inhibit a decrease in Ku and reduce magnetic interactions between ferromagnetic crystal particles, along with incorporating an appropriate amount of Cr.

It is also necessary to inhibit Co corrosion in terms of the environmental resistance. If a metallic protective film of Ti or the like is used for fully inhibiting the corrosion, for example, the total thickness of the protective film should be as large as 5 nm or greater. As a result, there are disadvantages that not only a magnetic spacing between a magnetic layer and a magnetic head expands to lower a sensitivity in reading, but also, in writing, a writing magnetic field generated from the head decreases.

As a result of diligent studies, the inventors have found that the reason why Ku decreases as the amount of Cr increases is that the crystallinity and orientation of ferromagnetic crystal particles are deteriorated by increasing the amount of Cr. Particularly, the inventors have found that deterioration at an initial growth region of the magnetic recording layer (portion of the interface (about 2 nm) between an under layer and a magnetic recording layer, if the underlayer is present) is significant, so that crystal growth continuing over the initial growth region is inhibited. Furthermore, if the deteriorated initial growth region is present, Co corrosion tends to increase. Generally, the amorphous material is poorer in corrosion resistance than the crystalline material. Accordingly, it could be considered as one of factors for increasing Co corrosion that Co atoms are precipitated to the surface of a magnetic film, from a portion of the initial growth region having approximately amorphous structure with a small defect as a trigger.

Means for Solving the Problems

The present invention has been made in view of the problems described above, and its object is to improve the crystallinity and orientation of an initial growth region, achieve compatibility between noise reduction and thermal stability, and achieve an improvement in medium performance, i.e. increase of recording density.

The present invention relates to a perpendicular magnetic recording medium made by sequentially stacking at least an underlayer, a magnetic recording layer, a protective layer and a lubricant layer on a nonmagnetic substrate, characterized in that the underlayer is composed from at least one element selected from Ru, Rh, Os, Ir and Pt, the magnetic recording layer contains at least Co, Pt, Cr and B and at least one of an oxide and a nitride, and the composition of the magnetic recording layer is such that the amount of Cr is 2 atom % or more and 12 atom % or less and the amount of boron (B) is 0.5 atom % or more and 5 atom % or less based on the total amount of Co, Pt, Cr and B, and the total amount of the oxide and nitride is 4 mol % or more and 12 mol % or less of the amount of the magnetic recording layer.

Furthermore, the magnetic recording layer preferably has a structure in which a nonmagnetic crystal particle boundary consisting of at least one of the oxide and nitride surrounds crystal particles consisting of Co, Pt, Cr and B which have a crystalline structure of hexagonal closest packing and are ferromagnetic.

Furthermore, crystal particles forming the magnetic recording layer are preferably epitaxially grown on crystal particles of the underlayer.

Furthermore, the oxide or nitride is preferably an oxide or a nitride of at least one element of Cr, Al, Ti, Si, Ta, Hf, Zr, Y and Ce.

Furthermore, a seed layer is preferably further provided immediately below the underlayer.

Furthermore, a soft magnetic backing layer is preferably further provided between the nonmagnetic substrate and the underlayer.

The present invention relates to a method for production of a perpendicular magnetic recording medium made by sequentially stacking at least an underlayer, a magnetic recording layer, a protective layer and a lubricant layer on a nonmagnetic substrate, characterized in that the underlayer is formed by a sputtering process using a target composed from at least one element selected from Ru, Rh, Os, Ir and Pt, and the magnetic recording layer is formed by a sputtering process using a target containing at least Co, Pt, Cr and B and at least one of an oxide and a nitride, and having a composition such that the amount of Cr is 2 atom % or more and 12 atom % or less and the amount of B is 0.5 atom % or more and 5 atom % or less based on the total amount of Co, Pt, Cr and B, and the total amount of the oxide and nitride is 4 mol % or more and 12 mol % or less of the amount of the magnetic recording layer.

The present invention relates to a magnetic recording apparatus characterized by having a perpendicular magnetic recording medium made by sequentially stacking at least an underlayer, a magnetic recording layer, a protective layer and a lubricant layer on a nonmagnetic substrate, wherein the underlayer is composed from at least one element selected from Ru, Rh, Os, Ir and Pt, the magnetic recording layer contains at least Co, Pt, Cr and B and at least one of an oxide and a nitride, and the composition of the magnetic recording layer is such that the amount of Cr is 2 atom % or more and 12 atom % or less and the amount of B is 0.5 atom % or more and 5 atom % or less based on the total amount of Co, Pt, Cr and B, and the total amount of the oxide and nitride is 4 mol % or more and 12 mol % or less of the amount of the magnetic recording layer.

### Advantages of the Invention

As described above, an underlayer is formed with Ru, Rh, Os, Ir, Pt or an alloy material composed from at least one selected from these elements, and the amounts of Cr, B, oxide and nitride contained in a CoPtCrB-M (wherein M is an oxide, a nitride or an oxide and nitride) magnetic recording layer formed immediately above the underlayer are appropriately set, whereby high Ku and low noises can be made mutually compatible.

If the amount of addition of B is 5 atom % or less and the underlayer is the aforementioned material when the Cr concentration is 12 atom % or less, most of B added is situated preferentially on crystal particles of the underlayer and becomes a nucleation site of ferromagnetic crystal particles. As a result, a favorable crystallinity is achieved at the initial stage of growth of the magnetic recording layer. In this connection, part of added B is situated at crystal particle boundaries of the underlayer, but oxidized or nitrided (or nitiridized) by oxygen or nitrogen contained in M which is a particle boundary component, and remains as a nonmagnetic boundary component to play the same role as that of M. If the amount of addition of B exceeds the range described above, Bisoxidized or nitrided on crystal particles of the underlayer, by oxygen or nitrogen contained in M. Namely, the crystal plane of the surface of the underlayer tends to be covered, and thereby resulting in deterioration of the crystallinity of the magnetic recording layer, the uniformity of crystal particles, or the like, oppositely. Owing to such an effect of B, Cr has a sufficient noise reduction effect in an amount of 12 atom % or less, and Ku does not decrease. The reason why the noise reduction effect is achieved with a relatively low Cr concentration as described above is that B becomes a nucleation site and serves as a starting point of growth of Co crystal particles, and resultantly, part of Cr which has previously existed in particles is segregated to particle boundaries. Namely, the segregated structure in the initial growth region of the magnetic recording layer is improved, the magnetic cluster size as well as magnetic interactions are reduced. In addition, an area of the initial growth region where the crystalline structure is out of order becomes small, migration of Co atoms is inhibited, and resultantly, Co corrosion is reduced. Thus, noise reduction, high thermal stability and high corrosion resistance of the granular magnetic recording layer can be achieved.

### BRIEF DESCRIPTION OF THE DRAWINGS

FIG. 1 is a schematic sectional view of a double layer perpendicular magnetic recording medium according to the present invention;

FIG. 2 is a schematic sectional view of a single layer perpendicular magnetic recording medium according to the present invention;

FIG. 3 is a graph showing a change in a perpendicular magnetic anisotropy constant Ku resulting from a change in the concentration of B and Cr;

FIG. 4 is a graph showing a change in a magnetic cluster size resulting from a change in the concentration of B and Cr;

FIG. 5 is a graph showing a change in a coercive force Hc resulting from a change in the concentration of SiN; and

FIG. 6 is graph showing a change in the eluted amount of Co resulting from a change in the concentration of B and Cr.

### DESCRIPTION OF SYMBOLS

1, 11 nonmagnetic substrate
2 soft magnetic backing layer
3, 13 seed layer
4, 14 underlayer
5, 15 magnetic recording layer
6, 16 protective layer
7, 17 lubricant layer
131 first seed layer
132 second seed layer

### BEST MODE FOR CARRYING OUT THE INVENTION

Embodiments of the present invention will be described below with reference to the drawings.

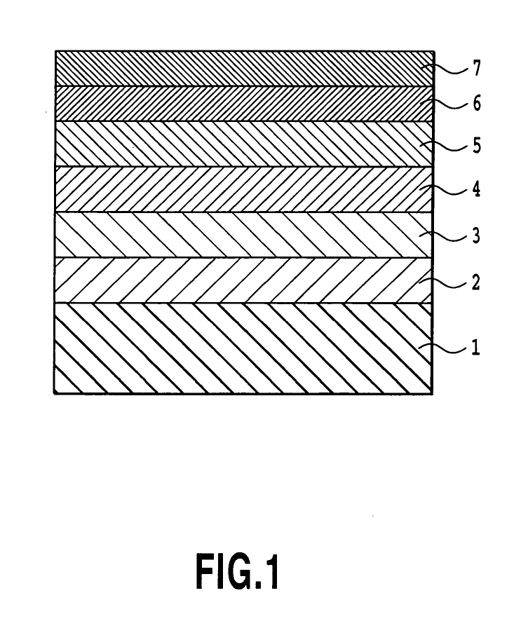

FIG. 1 is a view for explaining a first illustrative configuration of a perpendicular magnetic recording medium of the present invention, which has a configuration of a double layer perpendicular medium. The perpendicular magnetic recording medium has a soft magnetic backing layer 2, a seed layer 3, an underlayer 4, a magnetic recording layer 5 and a protective layer 6 which are sequentially stacked on a nonmagnetic substrate 1, and further, a lubricant layer 7 is formed on the protective layer 6.

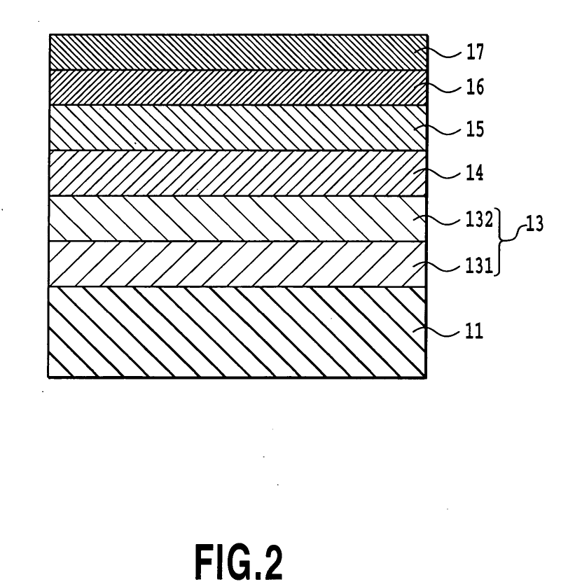

Furthermore, FIG. 2 is a view for explaining a second illustrative configuration of a perpendicular magnetic recording medium of the present invention, which has a configuration of a single layer perpendicular medium. The perpendicular magnetic recording medium has a seed layer 13 consisting of a multiple layers, an underlayer 14, a magnetic recording layer 15 and a protective layer 16 which are sequentially stacked on a nonmagnetic substrate 11, and further, a lubricant layer 17 is formed on the protective layer 16. The seed layer 13 consists of a first seed layer 131 and a second seed layer 132.

In the perpendicular magnetic recording medium of the present invention, an Al alloy or strengthened glass plated with NiP, which is used for a normal magnetic recording medium, a crystallized glass, or the like may be used for the nonmagnetic base support (nonmagnetic substrate) 1, 11. Furthermore, if the temperature for heating the substrate is limited to 100° C. or less, a plastic substrate made of a resin such as polycarbonates or polyolefins may be used.

The soft magnetic backing layer 2 is a layer which is preferably formed for improving recording and readout characteristics by controlling magnetic fluxes from a magnetic head for use in magnetic recording. The soft magnetic backing layer can be omitted. For the soft magnetic backing layer, crystalline alloys such as a NiFe alloy, a sendust (FeSiAl) alloy, aCoFe alloy or the like, or microcrystalline alloys such as FeTaC, CoFeNi, CoNiP or the like may be used. However, by using an amorphous Co alloy, for example CoNbZr or CoTaZr, a more favorable electromagnetic conversion characteristic can be obtained. An optimum thickness of the soft magnetic backing layer 2 varies depending on the structure and characteristics of the magnetic head for use in magnetic recording. However, it is preferably 10 nm or more and 500 nm or less in light of productivity, is such a case that the soft magnetic backing layer 2 is formed continuously along with other layers. Where the soft magnetic backing layer 2 is pre-formed on the nonmagnetic substrate by a plating process or the like before forming other layers, the thickness can be as large as several micrometers. The soft magnetic backing layer may become a noise source because it has magnetization. Noises caused by the soft magnetic layer can be inhibited by a method in which magnetization of the soft magnetic layer is fixed with a certain strength in an in-plane direction of the substrate by providing an anti ferromagnetic film or a hard magnetic film immediately below the soft magnetic backing layer (or immediately above the soft magnetic backing layer, or these films are alternately stacked), or a method in which the soft magnetic layer is stacked with the nonmagnetic layer.

The seed layer 3, 13 is a layer which is preferably formed immediately below the underlayer for improving the orientation of the underlayer 4, 14. The seed layer can be omitted. For the seed layer, a nonmagnetic material or a soft magnetic material may be used.

If the soft magnetic layer backing layer is formed under the seed layer 3, 13, a soft magnetic material is more preferably used, which is capable of acting as part of the soft magnetic layer backing layer.

The material of the seed layer 3, 13 showing a soft magnetic property may include a Ni base alloy such as NiFe, NiFeNb, NiFeB or NiFeCr, Co, or a Co base alloy such as CoB, CoSi, CoNi or CoFe. Co and Ni can be contained in the seed layer at the same time. Any of the materials preferably has a crystalline structure of face centered cubic lattice (fcc) or hexagonal closest packing (hcp) like the underlayer 4. In this connection, addition of Fe is effective for improving the soft magnetic property. However, in consideration of a lattice matching with the underlayer, the amount of addition of Fe is preferably 15% or less, further preferably 10% or less.

The material of the seed layer 3, 13 showing a nonmagnetic property may include a Ni base alloy such as NiP or NiFeCr, or a Co base alloy such as CoCr. Any of the materials preferably has a crystalline structure of face centered cubic lattice (fcc) or hexagonal closest packing (hcp) like the underlayer 4.

For the purpose of functionally separating security of a crystal lattice matching and control of a crystal particle diameter, any of the above soft magnetic and nonmagnetic materials can also be stacked to form multiple layers, for example the first seed layer 131 and the second seed layer 132.

When forming the first seed layer 131, a material for satisfactorily forming the second seed layer 132 can be selected as appropriate, and in addition to the materials described above, Ta, Ti, Cr, W, V or an alloy material thereof may be used to form the first seed layer. They may have a crystalline structure, or may have an amorphous structure.

As described above, the underlayer 4, 14 is a layer which is formed immediately below the magnetic recording layer for suitably controlling the crystal orientation, crystal particle diameter and particle boundary segregation of the magnetic recording layer 5, 15. The underlayer 4, 14, is prepared from one element selected from Ru, Rh, Os, Ir and Pt, or an alloy having elements selected from Ru, Rh, Os, Ir and Pt. If these materials are used, B contained in the magnetic recording layer is preferentially situated on crystal particles of the underlayer, and becomes a nucleation site of ferromagnetic crystal particles of the magnetic recording layer. In this connection, the total content of Ru, Rh, Os, Ir and Pt is preferably 90% orgreater forsufficiently obtaining such an effect, when using an alloy having elements selected from Ru, Rh, Os, Ir and Pt. The crystalline structure of the underlayer is preferably a hexagonal closest packing (hcp) structure or a face centered cubic lattice (fcc) structure in consideration of the lattice matching, in order to promote epitaxial growth of Co which is a main component of the magnetic recording layer immediately above the underlayer and has a hexagonal closest packing (hcp) structure. Furthermore, if the soft magnetic backing layer is provided, the underlayer is preferably rendered nonmagnetic for interrupting magnetic interactions between the magnetic recording layer and the soft magnetic backing layer. The thickness of the underlayer is not specifically limited, however in terms of improvement of recording and readout resolutions and productivity, it has preferably a minimum thickness required for control of the crystal structure of the magnetic recording layer, and preferably a thickness of 3 nm or greater allowing crystal growth of the underlayer itself to be sufficiently obtained.

The magnetic recording layer 5, 15 contain at least Co, Pt, Cr and B, and at least one of an oxide and a nitride.

Preferably, the magnetic recording layer is composed from ferromagnetic crystal particles having at least Co, Pt, Cr and B and nonmagnetic crystal particle boundaries surrounding the ferromagnetic crystal particles. The nonmagnetic crystal particle boundary is composed from at least one of an oxide and a nitride, and elements which are some of elements forming ferromagnetic crystal particles and segregated from the ferromagnetic crystal particles.

The oxide and the nitride do not form a solid solution with Co which constitutes magnetic particles, and easily form a separated structure. Namely, Co particles are physically separated each other, and therefore interactions between the particles can be reduced. Further, in the perpendicular medium, in the case of the conventional CoCr alloy containing neither an oxide nor a nitride, segregation of Cr is hard to occur and it is difficult to form a segregated structure in which Co particles are separated.

If magnetic particles consist of Co alone, the anisotropic property is low and the thermal stability is insufficient, and therefore the perpendicular magnetic anisotropy is enhanced by adding Pt.

For reducing interactions between particles, it is effective to physically separate magnetic particles by an oxide or a nitride as described above. However, if the width of the particle boundary is simply enlarged, the number of magnetic particles per unit area decreases, namely the number of magnetic particles contained per a “bit” decreases, and therefore this is not preferable in terms of thermal stability. Thus, Cr having an effect of reducing interactions between particles is added, in order to reduce interactions between particles even when the width of the particle boundary formed of an oxide or a nitride is small.

However, if the amount of addition of Cr is increased, Ku decreases, and hence the thermal stability is deteriorated. Thus, for inhibiting a decrease in Ku resulting from an increase in the amount of addition of Cr, the aforementioned underlayer is applied, and, moreover, B is added. In the manner described above, low noises and thermal stability can be made mutually compatible, and the corrosion resistance can be improved.

The composition ratio of the magnetic recording layer is such that Cr is 2 atom % or more and 12 atom % or less and B is 0.5 atom % or more and 5 atom % or less, based on the total amount of Co, Pt, Cr and B. The total amount of oxide and nitride is 4 mol % or more and 12 mol % or less of the amount of magnetic recording layer (i.e. on the basis of the total number of moles of materials forming the magnetic recording layer; the materials of ferromagnetic crystals are treated as a compound having their average composition, and, for example, in the case of Co₇₆Pt₁₅Cr₆B₃, the number of moles is calculated as a compound having an average molecular weight of 77.49).

By keeping the composition within the range described above, high Ku and low noises can be made mutually compatible, and the corrosion resistance can be improved. If the amount of addition of B is within the range described above, B is preferentially situated on crystal particles of the underlayer, and becomes a nucleation site of ferromagnetic crystal particles. As a result, magnetic particles of the magnetic recording layer achieve a favorable crystallinity at the initial stage of growth, leading to an increase in Ku and an improvement in corrosion resistance. If the amount of addition of B is greater than 5%, B is oxidized or nitrided by oxygen or nitrogen (which originates from an oxide or a nitride and does not form a compound) present in a slight amount in the magnetic recording layer, and does not function well, resulting in deterioration of the crystallinity conversely.

By adding Cr in an amount of 2 atom % or greater, the magnetic cluster size decreases to provide a noise reduction effect. On the other hand, if the amount of addition of Cr exceeds 12 atom %, Ku decreases and the thermal stability is deteriorated. Owing to the effect of B, Cr shows a noise reduction effect in a relatively low concentration range of 12 atom % or less, and moreover Ku does not decrease. The reason why the noise reduction effect is achieved with a Cr concentration lower than in the past, is that B becomes a nucleation site and serves as a starting point of growth of Co crystal particles, and resultantly, part of Cr, which would exist in ferromagnetic crystal particles if B is not added, is segregated to crystal particle boundaries. Namely, the segregated structure at the initial growth region of the magnetic recording layer is improved, and magnetic interactions are reduced.

Pt is added for increasing the perpendicular magnetic anisotropy. Ku increases as the amount of Pt is increased, however, if the amount becomes too large, the fcc structure (which is crystal orientation of Pt) becomes dominant, and therefore, Ku decreases oppositely. Thus, the amount of addition of Pt is preferably 40 atom % or less.

For the material forming ferromagnetic crystal particles, in addition to the aforementioned elements, elements such as Ni and Ta can appropriately added within the range not departing from the spirit of the present invention. Furthermore, it is not intended to exclude the case where a very small amount of elements, oxides and nitrides forming nonmagnetic crystal particle boundaries coexist in the ferromagnetic crystal particles.

The oxide or nitride is added for promoting formation of nonmagnetic crystal particle boundaries by segregation, and an oxide or a nitride of at least one element of Cr, Al, Ti, Si, Ta, Hf, Zr, Y and Ce is preferable. For mutual compatibility of noises and thermal stability of the magnetic recording layer, the amount of addition should be 4 mol % or more and 12 mol % or less, based on the amount of magnetic recording layer. If the amount of addition is less than 4 mol %, Hc decreases and noises increase, since separation of ferromagnetic crystal particles becomes insufficient. On the other hand, if the amount of addition exceeds 12 mol %, the crystal particle diameter decreases to, for example, about 4 nm or less, and resultantly, increasing the proportion of para magnetic particles changed from crystal particles which should be ferromagnetic by nature, and thereby Hc decreases and the problem of thermal fluctuations arises.

The magnetic recording layer preferably has a structure in which nonmagnetic crystal particle boundaries composed from an oxide or a nitride surround ferromagnetic crystal particles composed from Co, Pt, Cr and B and having a hcp structure. By such a configuration, magnetic interactions between ferromagnetic crystal particles are reduced to still further reduce noises.

For the protective layer 6, 16, conventionally used protective films may be used, and for example, a protective film having carbon as a main component may be used. Furthermore, for the lubricant layer 7, 17, conventionally used materials may be used, and for example, perfluoropolyether liquid lubricant may be used. Furthermore, for conditions such as the thickness of the protective layer and the thickness of the lubricant layer, conditions that are used for ordinary magnetic recording media may directly be used.

A magnetic recording apparatus of the present invention comprises at least recording means formed from the perpendicular magnetic recording medium of the present invention, driving means (spindle motor or the like) for driving (rotating) the recording means, read/write means including a writing head (magnetic monopole head or the like) and a reading head (GMR head or the like), position determining means (voice coil motor, and control portion etc. ) for moving the read/write means to an appropriate position on the platter (the recording means), and control means for communicating with external devices and controlling transmission of information to external devices and recording of information received from external devices (constituted by electronic components such as LSI, a connector for communication, and the like).

Examples of the method for production of the perpendicular magnetic recording medium of the present invention will be described below. In this connection, these examples are merely representative examples for suitably explaining the method for production of the perpendicular magnetic recording medium of the present invention, and the present invention is not limited to the examples.

### EXAMPLE 1

In this example, an example of fabrication with the amounts of addition of Cr and B changed in single layer perpendicular media having the configuration of FIG. 2 will be described.

As a nonmagnetic substrate 11, a chemically strengthened glass substrate (e.g. N-5 glass substrate manufactured by HOYA Corporation) having a smooth surface was used. This glass substrate was washed and then introduced into a sputtering apparatus, a first seed layer 131 consisting of amorphous Ta was formed in a thickness of 10 nm using a Ta target in Ar gas having a pressure of 5 mTorr. A second seed layer 132 consisting of nonmagnetic NiFeCr was then formed in a thickness of 15 nm in Ar gas having a pressure of 20 mTorr using a Ni₆₅Fe₂₀Cr₁₅ target (the subscript represents a composition ratio expressed by atom %. The same will apply hereinafter) as a nonmagnetic Ni base alloy. Further, an Ir underlayer 14 was formed in a thickness of 15 nm using an Ir target in Ar gas having a pressure of 30mTorr. Thereafter, a CoPtCrB—SiN magnetic recording layer 15 was formed in a thickness of 12 nm using a 93 mol % (CO_{85-X-y}Pt₁₅Cr_{X}B_{y})-7 mol % (SiN) target in Ar gas having a pressure of 30 mTorr. At this step, media with the amounts of addition of Cr and B changed within the range of x=2 to 14 and y=0 to 7 were fabricated. For comparison, a medium in which B was not added was also fabricated as a comparative example. Finally, a protective layer consisting of carbon was formed in a thickness of 4 nm using a carbon target, and the glass substrate was then removed from a vacuum apparatus. Thereafter, a liquid lubricant layer consisting of perfluoropolyether was formed in a thickness of 2 nm by a dipping method to obtain a single layer perpendicular medium.

RF sputtering was used for formation of the magnetic recording layer, and all other layers were formed by a DC magnetron sputtering process. The heat treatment of the substrate was not carried out.

### EXAMPLE 2

In this example, an example of fabrication with the amounts of addition of Cr and B changed in double layer perpendicular medium having a configuration of FIG. 1 will be described.

Double layer perpendicular media were fabricated all in the same manner as in example 1, except that an amorphous CoTaZr soft magnetic backing layer was formed in a thickness of 150 nm as a soft magnetic backing layer 2 using a Co₉₁Ta₄Zr₅ target, a seed layer 3 was a single layer consisting of nonmagnetic NiFeCr (corresponding to the second seed layer of example 1), and the first seed layer consisting of Ta was not formed.

### EXAMPLE 3

In this example, an example of fabrication with the amount of addition of SiN changed in single layer perpendicular media having the configuration of FIG. 2 will be described.

Single layer perpendicular media were fabricated all in the same manner as in example 1, except that when a CoPtCrB—SiN magnetic recording layer was formed as a magnetic recording layer, media with the amount addition of SiN changed within the range of z=2 to 14 were fabricated using a (100-z) mol % (CO₇₅Pt₁₅Cr₇B₃)-z mol % (SiN) target.

### EXAMPLE 4

In this example, an example of fabrication with the amount of addition of SiN changed in double layer perpendicular media having the configuration of FIG. 1 will be described.

Double layer perpendicular media were fabricated all in the same manner as example 2, except that when a CoPtCrB—SiN magnetic recording layer was formed as a magnetic recording layer, media with the added amount of SiN changed within the range of z=2 to 14 were fabricated using a (100-z) mol % (Co₇₅Pt₁₅Cr₇B₃)-z mol % (SiN) target.

(Action and Effect of Underlayer, and Amounts of Addition of Cr and B)

The results of evaluation of the magnetic recording media of examples 1 and 2 will be described. For the single layer perpendicular medium of example 1, the perpendicular magnetic anisotropy constant Ku was determined using a magnetic torque meter, and the magnetic cluster size was determined from images obtained by observing the surface of the medium after AC demagnetization with a magnetic force microscope (MFM) For the double layer perpendicular medium of example 2, the electromagnetic conversion characteristic was evaluated by a spin stand tester using magnetic monopole/GMR heads. In this connection, both of the first seed layer of the single layer perpendicular medium consisting of Ta and the CoTaZr soft magnetic backing layer of the double layer perpendicular medium have an amorphous structure, and therefore it can be considered that they do not influence the crystal orientation and microstructures of the upper NiFeCr seed layer (or the second seed layer), the following Ir underlayer and the CoPtCrB—SiN magnetic recording layer, and the characteristics of CoPtCrB-SiN magnetic recording layers of the single layer perpendicular medium coincides with that of the double layer perpendicular medium.

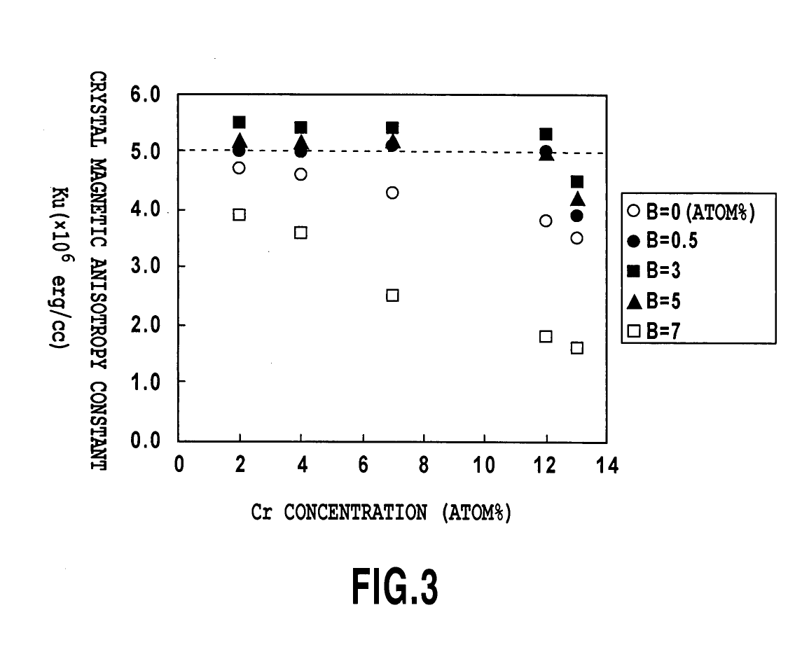

FIG. 3 shows dependencies of Ku on the Cr concentrations with the B concentration of 0, 0.5, 3, 5 and 7 atom %, respectively. In the case of B=0 atom % where B is not added, i.e. in the comparative example to the present invention, Ku monotonously decreases as the Cr concentration increases. In the case of B=0.5, 3, 5 atom %, Ku shows a high value of Ku=5.0×10⁶ erg/cc irrespective of the magnitude of the Cr concentration when the Cr concentration is 12 atom % or less, however Ku starts to decrease when the Cr concentration becomes greater than Cr=12 atom %. Thus, it can be seen that by addition of B, a nucleation site is formed on the surface of the underlayer, the crystallinity of ferromagnetic crystal particles is improved, and resultantly, Ku increases, and is independent of the Cr concentration and remains high when the Cr concentration is 12 atom % or less. In the case of B=7 atom %, Ku is lower than that of B=0 atom %, and the rate of decrease relative to the Cr concentration is high. It can be seen that this is because the amount of addition of B is so large that nitrided B (formed with nitrogen contained in SiN nonmagnetic particle boundary components) starts to appear, and the orientation of ferromagnetic crystal particles is interrupted deterioratively.

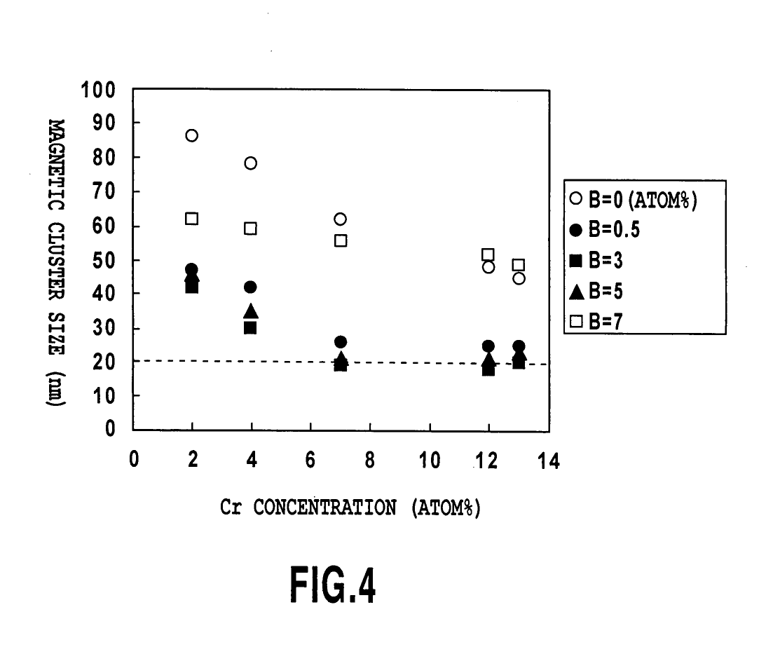

FIG. 4 shows dependencies of the magnetic cluster size on the Cr concentration with the B concentration of 0, 0.5, 3, 5 and 7 atom %, respectively. In the case of B=0 atom % where B is not added, i.e. in the comparative example to the present invention, the magnetic cluster size monotonously decreases as the Cr concentration increases, however the magnetic cluster size is very large, i.e. 86 nm, when the Cr concentration is low, for example Cr=2 atom %. In the case of B=0.5, 3, 5 atom %, the magnetic cluster size decreases as the Cr concentration increases. This tendency is similar to the tendency of B=0 atom %, however is different in that the magnetic cluster size is small even when the Cr concentration is low. For example, in the case of B=3 atom %, the magnetic cluster size is 42 nm, which is less than half of that of B=0 atom %, when the Cr concentration is Cr=2 atom %. The reason why the effect of reducing the magnetic cluster size is provided even at a relatively low Cr concentration as described above is that B becomes a nucleation site and serves as a starting point of growth of Co crystal particles, and resultantly, part of Cr which has previously existed in crystal particles is segregated to crystal boundaries. Namely, the segregated structure at the initial growth region of the magnetic recording layer is improved, and magnetic interactions are reduced. In the case of B=7 atom % where the amount of B is further increased, the magnetic cluster size is 49 to 62 nm, which is larger than that of B=0.5 to 5 atom %. This is because the segregated structure of the initial growth region is impaired by B which does not become a nucleation site but is nitrided as described above. Furthermore, it can be seen that the rate of reduction of the magnetic cluster size when increasing the Cr concentration is so small that segregation of Cr is hard to occur if nitrided B is present.

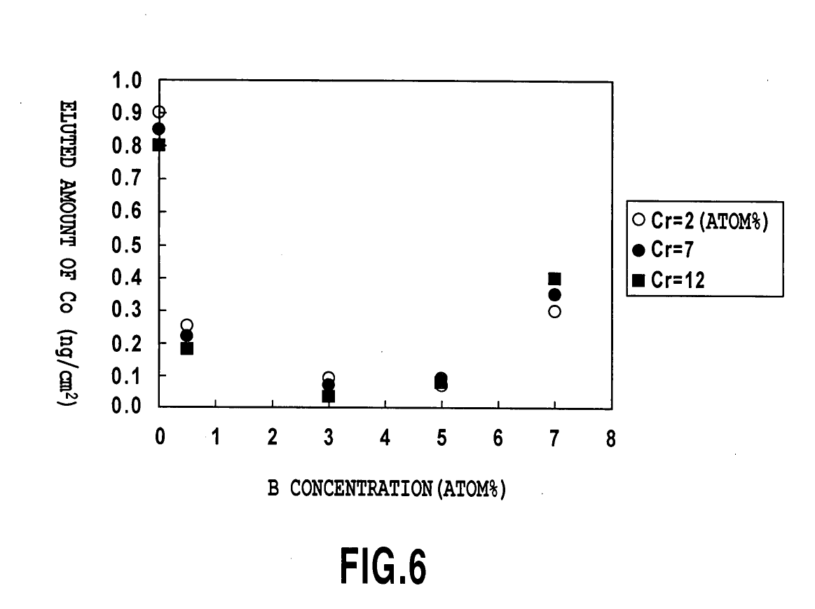

The amount of elution of Co was measured as evaluation of the corrosion resistance. The details are as follows. The magnetic recording medium was left standing under a high-temperature and high-humidity environment of a temperature of 85° C. and a relative humidity of 80% for 96 hours, the magnetic recording medium was then shaken in 50 ml of pure water for 3 minutes, eluted Co was extracted, the Co concentration in the pure water was measured by the ICP emission spectral analysis method, and the eluted amount of Co per unit surface area of the magnetic recording medium was calculated. The results of examining the amount of elution of Co for the double layer perpendicular medium fabricated in example 2 are shown in FIG. 6. FIG. 6 shows dependencies of the amount of elution of Co on the B concentration for Cr=2, 7 and 12 atom %, respectively. For the Cr concentration in this range, the amount of elution of Co was a minimum when the concentration of added B was in the range of 0.5 to 5 atom % in any case. As described above, it became apparent that addition of B is effective for improvement of the corrosion resistance as well.

For summarizing the results for Ku described in explanation with FIG. 3 and the results for the magnetic cluster size described in explanation with FIG. 4, the thermal stability is high with Ku>5.0×10⁶ erg/cc and the magnetic cluster size can extremely be reduced to about 20 nm when the Cr concentration is 12 atom % or less if B is added and the concentration of added B is 5 atom % or less. Furthermore, the amount of elution of Co also considerably decreased. Namely, it can be seen that compatibility between the thermal stability and noise reduction can be achieved, and, moreover, a high corrosion resistance can also be achieved.

Subsequently, the results of evaluation of the electromagnetic conversion characteristic of the double layer perpendicular medium will be described. The SNR at a linear recording density of 600 kFCI (kilo Flux Change per Inch) was evaluated, and as a result, the SNR was found to have a correlation with the magnetic cluster size, and the smaller the magnetic cluster size, the higher the SNR. For example, when the Cr concentration was 12 atom % and the B concentration was 0, 0.5, 3, 5, and 7 atom %, the SNR was 3.9, 8.1, 8.4, 8.2 and 4.1 dB, respectively. When B was added in an amount of 5 atom % or less, the SNR increased by 4.0 dB or greater, namely by two fold, compared to the case where B was not added. Further, a variation with time in a signal written at a linear recording density of 100 kFCI was evaluated. As a result, the rate of signal deterioration tended to decrease as Ku increased or the magnetic cluster size increased. Particularly, the signal deterioration for Ku>5.0×10⁶ erg/cc was extremely small, i.e. −0.01%/decade or less. For example, when the Cr concentration was 12 atom % and the B concentration was 0, 0.5, 3, 5 and 7 atom % as previously described as an example in the explanation for the SNR, the signal deterioration was −0.12, −0.002, −0.005, −0.004 and −4.71%/decade, respectively. In consideration of these results along with the previously described results for the SNR, it can be seen that when B is added in an amount of 5 atom % or less, the double layer perpendicular medium has an excellent thermal stability and a high SNR. These results reflect the results for Ku and the magnetic cluster size described above.

Examples in which the SiN concentration was fixed to 7 mol % have been described in examples 1 and 2, however, similar results were obtained for addition of B even when the SiN concentration was in the range of 4 to 12 mol %. Namely, as long as the concentration of nonmagnetic particle boundary components is appropriate, and the segregated structure in which nonmagnetic crystal particle boundaries surround ferromagnetic crystal particles is formed, the effect of addition of B can be exhibited. Furthermore, even when the amount of Pt changed, the aforementioned tendency remained unchanged and the effect of addition of B was observed.

The case where nonmagnetic particle boundary components are nitrides of Si was described in examples 1 and 2, however it has been confirmed that the precisely same effect is exhibited, even if the components are oxides such as SiO₂, or oxides or nitrides of Cr, Al, Ti, Ta, Hf, Zr, Y and Ce.

(Action and Effect of Oxides and Nitrides)

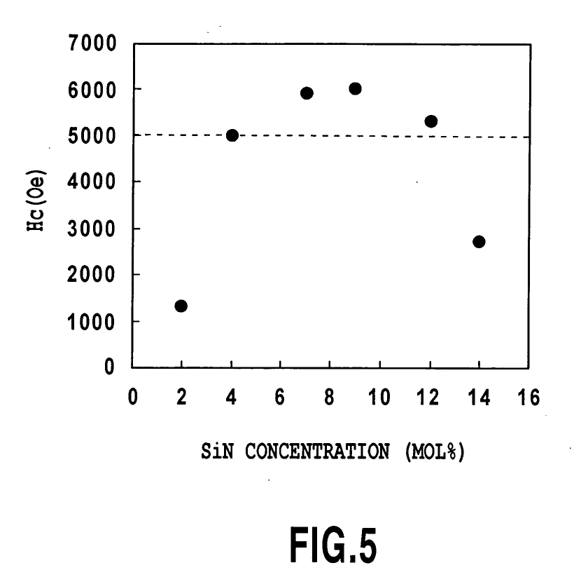

The results of evaluation of the magnetic recording media of examples 3 and 4 will now be described. For the single layer perpendicular medium of example 3, a coercive force Hc was determined by a hysteresis loop obtained using a vibration sample type magnetometer (VSM). For the double layer perpendicular medium of example 4, an electromagnetic conversion characteristic was evaluated by spin stand tester using magnetic monopole/GMR heads, and a SNR at a linear recording density of 600 kFCI was determined. FIG. 5 shows dependency of Hc on the SiN concentration. Hc abruptly increases at 2 to 4 mol %, then reaches a maximum value at around 8 mol % and abruptly decreases at 12 to 14 mol %. If the SiN concentration is too low, no segregated structure is formed, and Hc is low. If the SiN concentration is too high, the crystal particle size decreases to about 4 nm or less, the proportion of para magnetic particles increases, and Hc decreases due to influences of thermal fluctuations. It can be seen that a satisfactory segregated structure is formed at 4 to 12 mol % with Hc>5000 Oe in this example. The variation of the SNR with the SiN concentration obtained from the evaluation of the electromagnetic conversion characteristic coincided with the aforementioned tendency of Hc. The reason why the SNR was low when the SiN concentration was low is that formation of the segregated structure was insufficient, the magnetic cluster size was large and noises were high. The reason why the SNR was deteriorated when the SiN concentration was high is that influences of a drop in signal output by thermal fluctuations were significant. Thus, it can be seen that for forming a segregated structure, it is necessary to optimize the concentration of nonmagnetic particle boundary components in the first place.

The case where the nitride is SiN has been described in examples 3 and 4, however it has been confirmed where the condition of 0<a≦40, 2≦b≦12 and 0.5≦c≦5 is met in (100-d) mol % (Co_{100-a-b-c}PtₐCr_{b}B_{c})-d mol % M (M is an oxide or a nitride of at least one element of Cr, Al, Ti, Si, Ta, Hf, Zr, Y and Ce), the Hc and SNR have a maximum value in the range of 4≦d≦12.

In this connection, the underlayer consisted of Ir in examples 1 to 4, however for Ru, Rh, Os, Pt or an alloy material consisting of these elements, the precisely same results as those for the Ir underlayer were obtained. Same experiments were conducted using another element, i.e. Ti or Ni, having a crystalline structure of hcp or fcc and considered to be suitable for control of the orientation of the magnetic recording layer, however, the effect of addition of B was not observed, and Ku monotonously decreased as the amount of addition of B was increased. Thus, in order that B contained in the magnetic recording layer can become a nucleation site, the material of the underlayer should be Ru, Rh, Os, Ir, Pt or an alloy material consisting of these elements.

1. A perpendicular magnetic recording medium made by sequentially stacking at least an underlayer, a magnetic recording layer, a protective layer and a lubricant layer on a nonmagnetic substrate,
characterized in that said underlayer is composed from at least one element selected from Ru, Rh, Os, Ir and Pt,
said magnetic recording layer contains at least Co, Pt, Cr and B and at least one of an oxide and a nitride, and
the composition of said magnetic recording layer is such that the amount of Cr is 2 atom % or more and 12 atom % or less and the amount of B is 0.5 atom % or more and 5 atom % or less based on the total amount of Co, Pt, Cr and B, and the total amount of said oxide and nitride is 4 mol % or more and 12 mol % or less of the amount of said magnetic recording layer.

2. The perpendicular magnetic recording medium according to claim 1, characterized in that said magnetic recording layer has a structure in which a nonmagnetic crystal particle boundary composed from at least one of said oxide and nitride surrounds crystal particles composed from Co, Pt, Cr and B which have a crystalline structure of hexagonal closest packing and are ferromagnetic.

3. The perpendicular magnetic recording medium according to claim 1, characterized in that crystal particles forming said magnetic recording layer are epitaxially grown on crystal particles of said underlayer.

4. The perpendicular magnetic recording medium according to claim 1, characterized in that said oxide or nitride is an oxide or a nitride of at least one element of Cr, Al, Ti, Si, Ta, Hf, Zr, Y and Ce.

5. The perpendicular magnetic recording medium according to claim 1, characterized in that a seed layer is further provided immediately below said underlayer.

6. The perpendicular magnetic recording medium according to claim 1, characterized in that a soft magnetic backing layer is further provided between said nonmagnetic substrate and said underlayer.

7. A method for production of a perpendicular magnetic recording medium made by sequentially stacking at least an underlayer, a magnetic recording layer, a protective layer and a lubricant layer on a nonmagnetic substrate,
characterized in that said underlayer is formed by a sputtering process using a target composed from at least one element selected from Ru, Rh, Os, Ir and Pt, and
said magnetic recording layer is formed by a sputtering process using a target containing at least Co, Pt, Cr and B and at least one of an oxide and a nitride, and having a composition such that the amount of Cr is 2 atom % or more and 12 atom % or less and the amount of B is 0.5 atom % or more and 5 atom % or less based on the total amount of Co, Pt, Cr and B, and the total amount of said oxide and nitride is 4 mol % or more and 12 mol % or less of the amount of said magnetic recording layer.

8. A magnetic recording apparatus having a perpendicular magnetic recording medium made by sequentially stacking at least an underlayer, a magnetic recording layer, a protective layer and a lubricant layer on a nonmagnetic substrate,
characterized in that said underlayer is composed from at least one element selected from Ru, Rh, Os, Ir and Pt,
said magnetic recording layer contains at least Co, Pt, Cr and B and at least one of an oxide and a nitride, and
the composition of said magnetic recording layer is such that the amount of Cr is 2 atom % or more and 12 atom % or less and the amount of B is 0.5 atom % or more and 5 atom % or less based on the total amount of Co, Pt, Cr and B, and the total amount of said oxide and nitride is 4 mol % or more and 12 mol % or less of the amount of said magnetic recording layer.
